(19) United States
(12) Patent Application Publication
(10) Pub. No.: US 2010/0075037 A1
(43) Pub. Date: Mar. 25, 2010

(54) Deposition Systems, ALD Systems, CVD Systems, Deposition Methods, ALD Methods and CVD Methods

(76) Inventors: Eugene P. Marsh, Boise, ID (US); Tim Quick, Boise, ID (US); Stefan Uhlenbrock, Boise, ID (US); Brenda Kraus, Boise, ID (US)

Correspondence Address: WELLS ST. JOHN P.S., 601 W. FIRST AVENUE, SUITE 1300, SPOKANE, WA, 99201, US

(21) Appl. No.: 12/235,147

(22) Filed: Sep. 22, 2008

(51) Int. Cl. C23C 14/22; C23C 16/54

(52) U.S. Cl. 427/255.28; 118/710; 427/255.26

(57) ABSTRACT

Some embodiments include deposition systems configured for reclaiming unreacted precursor with one or more traps provided downstream of a reaction chamber. Some of the deposition systems may utilize two or more traps that are connected in parallel relative to one another and configured so that the traps may be alternately utilized for trapping precursor and releasing trapped precursor back into the reaction chamber. Some of the deposition systems may be configured for ALD, and some may be configured for CVD.

### TECHNICAL FIELD

Deposition Systems, atomic layer deposition (ALD) systems, chemical vapor deposition (CVD) systems, deposition methods, ALD methods and CVD methods.

### BACKGROUND

Integrated circuit fabrication frequently comprises deposition of materials across a semiconductor substrate. A semiconductor substrate may be, for example, a monocrystalline silicon wafer, either alone, or in combination with one or more other materials.

The deposited materials may be conductive, insulative, or semiconductive. The deposited materials may be incorporated into any of numerous structures associated with an integrated circuit, including, for example, electrical components, insulative material electrically isolating electrical components from one another, and wiring electrically connecting electrical components to one another.

ALD and CVD are two commonly utilized deposition methods. For ALD processing, reactive materials are sequentially provided in a reaction chamber at substantially non-overlapping times relative to one another to form a monolayer over a substrate. Multiple monolayers may be stacked to form a deposit to a desired thickness. ALD reactions are controlled so that a deposited material is formed along a substrate surface, rather than throughout a reaction chamber. In contrast, CVD processing comprises simultaneous provision of multiple reactive materials within a reaction chamber so that deposited material is formed throughout a reaction chamber, and then settles on a substrate within the chamber to form a deposit across the substrate.

Some reactive materials utilized for ALD and CVD are much more expensive than others. In some embodiments of this disclosure, the expensive reactive materials utilized for ALD and CVD may be categorized as being precursors, and the less expensive reactive materials may be categorized as being reactants. Precursors may contain metals; and may be complex molecules, such as metallorganic compositions. Reactants, in contrast, may be simple molecules, with common reactants being oxygen (O₂), ozone, ammonia and chlorine (Cl₂).

The precursors may be more valuable than their constituent parts. For instance, precursors comprising precious metals (e.g., gold, platinum, etc.) are often several times more expensive than the precious metals themselves. Also, precursors of relatively inexpensive materials (for instance, non-precious metals, like copper) may still be themselves expensive, particularly if complicated and/or low-yield processes are utilized in forming the precursors.

It would be desirable to develop systems and methods which reduce expenses associated with precursor materials.

### BRIEF DESCRIPTION OF THE DRAWINGS

FIG. 1 is a schematic diagram of an example embodiment deposition apparatus.

FIG. 2 is a schematic diagram of another example embodiment deposition apparatus.

FIG. 3 is a graphical illustration of an example pulse, purge, trap and bypass sequence that may be used during formation of a deposit utilizing the deposition apparatus of FIG. 2.

FIG. 4 is a schematic diagram of another example embodiment deposition apparatus.

### DETAILED DESCRIPTION OF THE ILLUSTRATED EMBODIMENTS

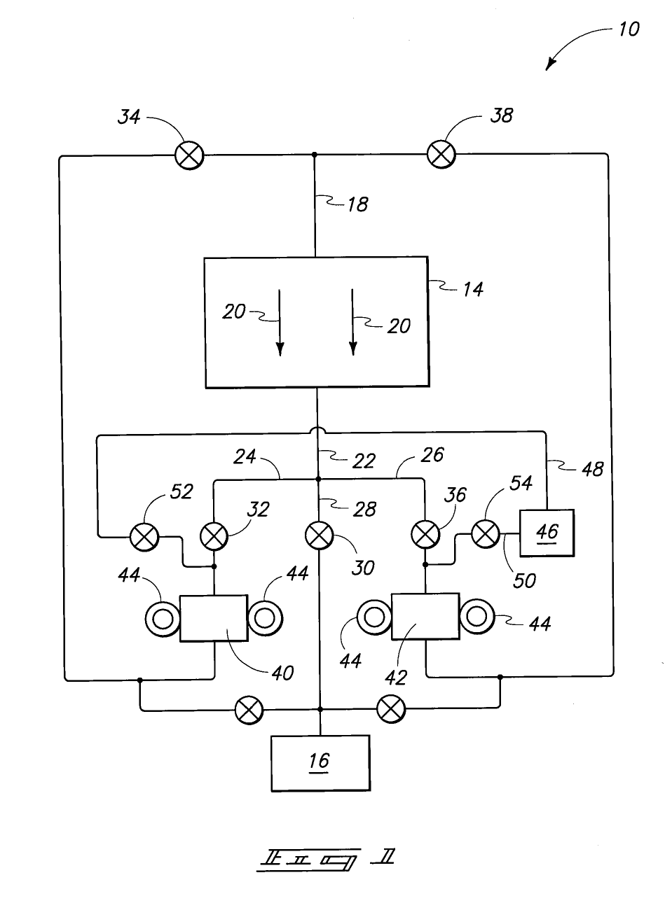

One aspect common to both ALD and CVD is that some of the precursor material that is introduced into a reaction chamber will remain unreacted, and thus will be exhausted from the chamber in the same compositional form in which it entered the chamber. Some embodiments include methods and systems suitable for reclaiming the unreacted precursor material so that it may be reintroduced into a deposition process. Example embodiments are described with reference to FIGS. 1-4.

Referring to FIG. 1, such illustrates a deposition system 10 configured for recycling trapped precursor material. System 10 includes a reaction chamber 14. The reaction chamber may be configured for one or both of ALD and CVD (with the term CVD being utilized herein to include traditional CVD, and to also include derivatives of traditional CVD processes, such as, for example, pulsed CVD).

A pump 16 is provided downstream of the reaction chamber and utilized to pull various materials through the system. Other components (not shown) may be provided in addition to, or alternatively to, pump 16 for assisting the flow of materials through the system. The materials flowing into and through the chamber may be considered to be flowed along a flow path that extends to the chamber along a line 18, through the chamber as illustrated by arrows 20, and then from the chamber along a line 22. The flow through the chamber may be continuous, or may comprise loading the chamber with a pulse of material, holding the material within the chamber for a duration of time, and then exhausting the material from the chamber with a purge cycle. If ALD is utilized, two or more sequential pulse/purge cycles may be utilized to form a monolayer of material.

The lines 18 and 22 may correspond to pipes or other suitable conduits for carrying materials to and from the reaction chamber. In addition to the lines 18 and 22, the system also includes lines 24, 26 and 28.

A valve 30 is shown along line 28, valves 32 and 34 are shown along line 24, and valves 36 and 38 are shown along line 26. The valves may be utilized to regulate flow of material along the flow path.

A pair of precursor traps 40 and 42 are shown along the lines 24 and 26, respectively. The precursor traps are configured to trap precursor under a first condition, and to release the trapped precursor under a second condition. For instance, the precursor traps may be cold traps and accordingly may be configured to trap precursor under a relatively low-temperature condition, and to release precursor under a relatively high-temperature condition. The terms “relatively low temperature” and “relatively high temperature” are utilized for comparison to one another so that the “relatively low-temperature” is a lower temperature than the “relatively high temperature”.

The specific temperatures may be any temperatures suitable for trapping and releasing precursors utilized during deposition with system 10. For instance, in some embodiments the platinum precursor (CH₃)₃(CH₃C₅H₄)Pt may be utilized. Such precursor may be trapped at a temperature less than about 0° C., such as, for example, a temperature of less than or equal to about −10° C. for ALD applications, and possibly less than or equal to about −20° C. for CVD applications; and such precursor may be released from the trap at a temperature greater than about 25° C., such as, for example, a temperature greater than about 40° C. In some embodiments, the trapping temperature may be low enough so that oxygen-sensitive material do not oxidize when exposed to air in a trapping line. For instance, if Rh is to be trapped, the trap may be at a temperature of less than or equal to −40° C. (where the term “−40° C.” means 40 degrees below 0° C.) during the trapping of the Rh, and during the retention of the Rh on the trap, to avoid oxidation of the Rh by oxygen that may be passed through the trap. The maintaining of a trapping temperature at a level cold enough to preclude oxidation of an oxygen-sensitive precursor (which may be an air sensitive precursor in some applications) may be considered to be one example of embodiments in which the trapping temperature is kept cold enough to preclude undesired side reactions from occurring relative to trapped materials. Such embodiments may be particularly suitable when trapping is utilized relative to CVD applications, since multiple reactive materials will be passed through traps while the traps are being utilized to retain desired precursors.

Coils 44 are diagrammatically illustrated adjacent the traps 40 and 42. The coils represent heating/cooling units that may be provided proximate the traps to control trapping and release of precursor from the traps in embodiments in which the traps may be thermally controlled (for instance, in embodiments in which the traps are cold traps).

The traps 40 and 42 may be considered to be in fluid communication with reaction chamber 14, and may be considered to be connected in parallel relative to one another along the flow path of material within system 10.

In operation, one of the traps 40 and 42 may be utilized as a source of precursor to chamber 14, while the other is utilized for trapping precursor present in the exhaust from chamber 14. In the shown embodiment, a carrier gas source 46 is illustrated to be in fluid communication with traps 40 and 42 through lines 48 and 50, respectively. Valves 52 and 54 are shown along lines 48 and 50 for controlling flow of the carrier gas to the traps 40 and 42. The carrier gas can assist in removing precursor from the traps. The carrier gas may be a composition inert relative to reaction with the precursor material under the conditions in which the precursor is released from the traps, and may, for example, comprise one or more of N₂, argon and helium.

The traps 40 and 42 may be alternately cycled between trapping and releasing modes relative to one another so that each of the traps is ultimately utilized as a source of precursor upstream of the reaction chamber, and is utilized for trapping unreacted precursor downstream of the reaction chamber.

Although two precursor traps are illustrated in the shown embodiment, in other embodiments there may be more than two precursor traps. For instance, multiple different precursors may be flowed through reaction chamber 14 during a deposition process, and it may be desired to trap the different precursors on separate traps relative to one another. In some embodiments, two traps arranged in parallel with one another may be utilized for trapping and releasing each of the different precursors. For instance, if a deposition process forms a mixed-metal material, such as platinum-ruthenium-oxide, each metal may be deposited from a separate precursor. It may be desired to trap the different metal-containing precursors separately from one another. The traps utilized for trapping different precursor materials may be identical to one another and utilized under different conditions from one another, or may be of different types relative to one another.

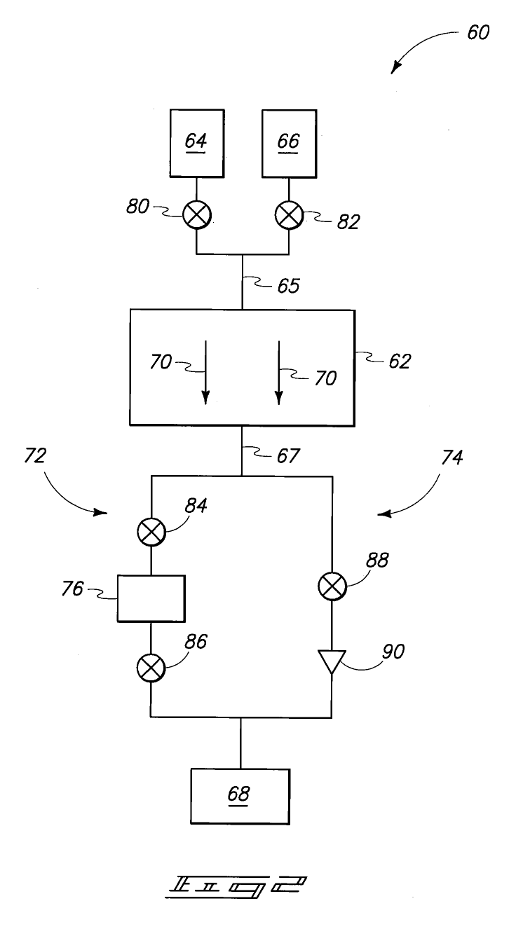

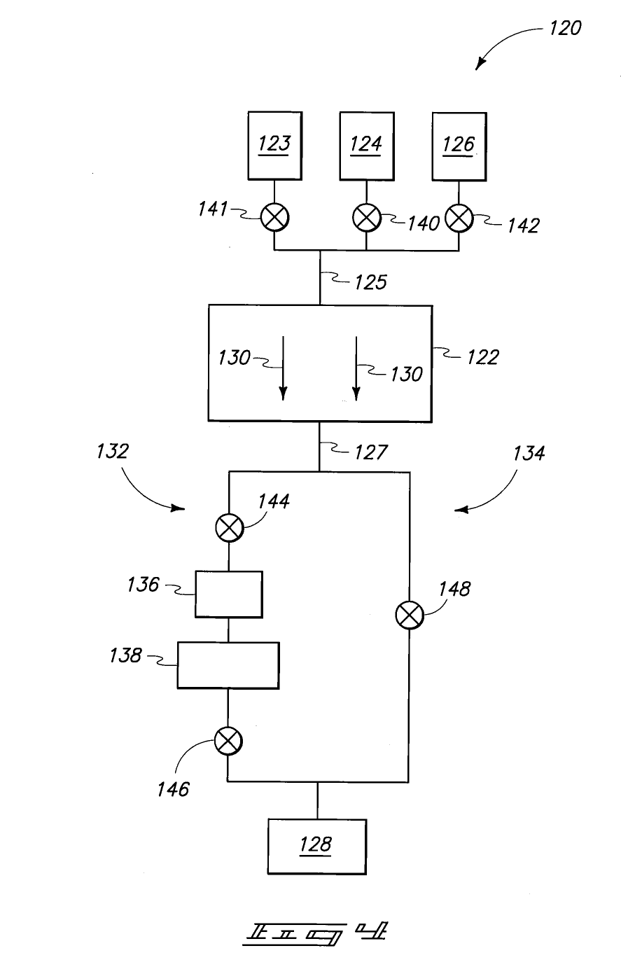

In embodiments in which reactant is utilized in addition to precursor, it may be desired to trap the precursor (in other words, to trap the expensive starting material), and to not trap the reactant (in other words, to not trap the cheap starting material). If the deposition process is an ALD process, the reactant may be exhausted from the system by a bypass similar to that discussed below with reference to FIG. 2; and if the deposition process is a CVD process the precursor traps may be utilized under conditions such that the reactant flows across the traps while precursor is retained on the traps in a manner similar to that discussed below with reference to FIG. 4.

The system 10 of FIG. 1 utilizes only traps 40 and 42 as sources of precursor material for a deposition process. In other embodiments, additional lines may be provided so that precursor may be additionally introduced into the reaction chamber from other sources besides the traps. The introduction of precursor from such other sources besides the traps may supplement the precursor provided by traps 40 and 42, and/or may be used to initiate a deposition process.

The system 10 of FIG. 1 is configured for continuously recycling precursor material. In other embodiments, a deposition system may be configured for trapping precursor material, but not for continuously recycling the precursor material. Rather, the system may be configured so that the material is removed from the trap during a recovery procedure occurring after a deposition process. The material may then be cleaned, if such cleaning is deemed desirable or necessary, and may then be utilized as source material during a subsequent deposition process. The utilization of a recovery procedure occurring subsequent to a deposition process may enable techniques to be utilized for removing precursor material from the trap that would be impractical to utilize in the continuous cycling system of FIG. 1. For instance, a trap may be pulled out of a deposition system and flushed with solvent to remove precursor material. Of course, thermal changes of the type discussed above with reference to FIG. 1 may be utilized additionally, or alternatively, to the solvent extraction methods.

FIG. 1 shows a couple of lines and valves which are not labeled, but which may enable the traps to be utilized—instead of being “dead legs” in the system.

FIG. 2 shows an ALD system 60 configured for recovery of precursor material from a trap in a procedure subsequent to, and separate from, a deposition process.

System 60 includes a reaction chamber 62, a pair of reservoirs 64 and 66 for retaining starting materials, and a pump 68 configured to be utilized for pulling various materials through the system. Other components (not shown) may be provided in addition to, or alternatively to, pump 68 for assisting the flow of materials through the system. The materials flowing into and through the chamber may be considered to be flowed along a flow path that extends to the chamber along a line 65, through the chamber as illustrated by arrows 70, and then from the chamber along a line 67. The line 67 splits into two alternative flow paths 72 and 74. The flow path 72 extends through a precursor trap 76, and the flow path 74 bypasses the precursor trap.

A plurality of valves 80, 82, 84, 86 and 88 are provided to enable regulation of the flow of various materials along the various flow paths extending to and from the reaction chamber. Other valves may be utilized in addition to, or alternatively to, the shown valves.

A flow control structure 90 is provided along flow path 74 and configured to preclude back-flow along the flow path. Flow control structure 90 may be any suitable structure, and may, for example, correspond to a turbopump, cryopump, destruct unit (i.e., a unit which breaks down one or more chemical compositions), or check-valve.

In operation, a precursor material may be provided in reservoir 64 and a reactant may be provided in reservoir 66. Valves 80 and 82 are utilized to control flow of the reactant and precursor so that only one of them is introduced into chamber 62 at any given time. Accordingly, the two different materials (specifically, the precursor and the reactant) are in chamber 62 at different and substantially non-overlapping times relative to one another. This may occur by removing substantially all of one of the materials from within the reaction chamber prior to introducing the other of the materials into the chamber. The term “substantially all” indicates that an amount of material within the reaction chamber is reduced to a level where gas phase reactions with subsequent materials do not degrade the properties of a deposit formed on a substrate from the material. Such can, in some embodiments, indicate that all of a first material is removed from the reaction chamber prior to introducing a second material, or that at least all measurable amounts of the first material are removed from the reaction chamber prior to introducing the second material into the chamber.

At times that precursor flows out of chamber 62, the exhaust from the chamber may be flowed along the flow path 72. Accordingly, the precursor may be trapped on the precursor trap 76 whereupon it may be subsequently reclaimed. The precursor is likely to flow out of chamber 62 during a flow of material through the chamber to fill the chamber with the precursor material, and during a flush of the chamber to remove precursor material from within the chamber.

At times when precursor is not being flowed out of the chamber, but instead materials other than precursor are flowed out of the chamber, the exhaust from the chamber may be flowed along bypass path 74. An advantage of flowing reactant along the bypass path 74 is that such may preclude undesired interaction of the reactant with precursor retained by trap 76, which could degrade the quality of the retained precursor.

Utilization of the flow control structure 90 along the bypass path 74 may advantageously preclude backflow of reactant into chamber 62. If reactant back flows into chamber 62, it may remain in the chamber when precursor is subsequently introduced to the chamber, which can lead to undesired CVD reactions between the precursor and reactant. Even if the reaction chamber is carefully monitored to ensure that substantially all reactant has been removed from the chamber prior to introduction of precursor, the backflow of reactant may lead to undesired consequences. Specifically, the backflow of reactant may lead to a much longer evacuation time than may be accomplished utilizing the shown embodiment in which a control structure 90 is provided to preclude backflow. A prior art ALD system is described in U.S. Patent Publication No. 2005/0016453. Such system lacks a flow control structure analogous to structure 90, and thus the system 60 shown and described with reference to FIG. 2 represents an improvement over such prior art ALD system.

Valve 86 may advantageously allow trap 76 to be isolated from a pumping line, which may improve precursor recovery rates relative to systems that leave the trap under dynamic vacuum.

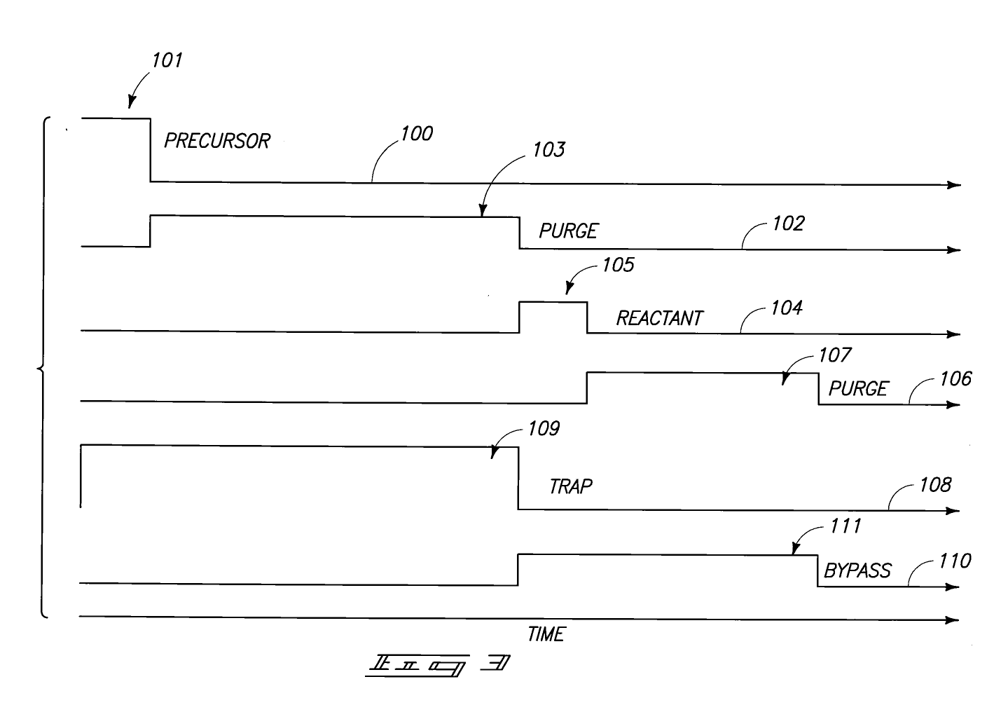

An example pulse/purge sequence that may be utilized with the system 60 of FIG. 2 is graphically illustrated in FIG. 3. The flow of precursor is illustrated with an uppermost path 100. Initially, a pulse of precursor is introduced into the chamber (with the chamber being labeled as 62 in FIG. 2) to fill the chamber with the precursor, and to provide sufficient time for reaction of the precursor with a surface of a substrate present in the chamber (the substrate is not shown in FIG. 2, but may be, for example, a semiconductor wafer). The pulse of precursor is diagrammatically illustrated as a region labeled 101 along the path 100. In some embodiments, the precursor may comprise metal, such as, for example, palladium, platinum, yttrium, aluminum, iridium, silver, gold, tantalum, rhodium, ruthenium or rhenium. In some embodiments, the precursor may comprise a transition metal and/or a lanthanide series metal (where the term “lanthanide series metal” refers to any of the elements having an atomic number from 57-71). If the precursor comprises platinum, such may be in the form of, for example, (CH₃)₃(CH₃C₅H₄)Pt. In some embodiments, the precursor may comprise semiconductor material, such as, for example, silicon or germanium.

After the precursor has been provided within the reaction chamber and given sufficient time to react with a surface of a substrate, a purge is utilized to remove the precursor from the chamber. Such purge is illustrated by the path 102 in FIG. 3. The duration of the purge is illustrated as a region labeled 103 along the path 102.

The exhaust from chamber 62 (FIG. 2) is passed across trap 76 (FIG. 2) during the pulse of precursor, and during the subsequent purge of precursor from the chamber, as illustrated by the path 108 of FIG. 3; with the flow through the trap occurring for a duration illustrated by a region labeled 109 along the path 108.

After precursor has been purged from the chamber, reactant is introduced into the chamber with a pulse as indicated by path 104 of FIG. 3. The pulse of the reactant occurs at a region labeled 105 along path 104. The pulse is of a suitable duration to fill the chamber with reactant, and to allow the reactant enough time to react with precursor at the surface of the substrate within the chamber. In some embodiments, the reactant may comprise oxygen (for instance, reactant may be in the form of O₂, water or ozone), or ammonia; and may be utilized to form an oxide or nitride in combination with the precursor. For instance, if the precursor comprises metal, and the reactant comprises oxygen or ammonia, the combination of reactant and precursor may form metal oxide or metal nitride.

After the pulse of reactant has been provided within the reaction chamber, a purge is utilized to remove the reactant from the chamber. Such purge is illustrated by the path 106 of FIG. 3. The duration of the purge is illustrated as a region labeled 107 along the path 106.

The exhaust from chamber 62 (FIG. 2) is passed along the bypass flow path (path 74 of FIG. 2) during the pulse of reactant, and during the subsequent purge of reactant from the chamber, as illustrated by the path 110 of FIG. 3. The flow along the bypass path occurs for a duration illustrated by the region 111 along the path 110.

The pulse/purge sequence of FIG. 3 may be repeated multiple times to form a deposit to a desired thickness. Accordingly, the pulse of precursor may be followed by a pulse of reactant which in turn is followed by a pulse of precursor, etc., which may lead to multiple pulses of precursor going across the precursor trap in a single deposition sequence. The precursor trap may be cleaned at any suitable time intervals. It may be desired to clean the trap with sufficient regularity so that the precursor-retaining properties of the trap are not compromised by approaching a saturation limit of precursor on the trap.

It is noted that the could be pump cycles (no gas flow) after the purge cycles of FIG. 3, or instead of the purge cycles.

The system of FIG. 2 is configured for an ALD process. One or more precursor traps may also be integrated into a CVD system for recovery of CVD precursors. FIG. 4 shows a CVD system 120 configured for recovery of precursor material.

System 120 includes a reaction chamber 122, a plurality of reservoirs 123, 124 and 126 for retaining starting materials, and a pump 128 configured to be utilized for pulling various materials through the system. Other components (not shown) may be provided in addition to, or alternatively to, pump 128 for assisting the flow of materials through the system. The materials flowing into and through the chamber may be considered to be flowed along a flow path that extends to the chamber along a line 125, through the chamber as illustrated by arrows 130, and then from the chamber along a line 127. The line 127 splits into two alternative flow paths 132 and 134. The flow path 132 extends through a pair of precursor traps 136 and 138 that are arranged in series with one another, and the flow path 134 bypasses the precursor traps.

The system 120 may be configured to utilize multiple different precursors simultaneously in a CVD process, and the traps 136 and 138 may be configured to separately trap different precursors relative to one another. For instance, if the CVD process utilizes a mixture of metal-containing precursors, one of the traps 136 and 138 may be configured to trap one type of metal-containing precursor, and the other of the traps may be configured to trap a different type of metal-containing precursor.

In some embodiments, the traps 136 and 138 may both be cold traps, with one of the traps operated at a different temperature than the other so that each trap selectively retains a particular precursor. For instance, the upstream trap 136 may be utilized at a temperature such that one precursor is retained, and another flows through; and the downstream trap 138 may be utilized at a temperature low enough to trap the precursor that flowed through the upstream trap.

In some embodiments, traps 136 and 138 may be different types of traps from one another. For instance, one may be a cold trap and the other may be a solvent-based trap.

Although two traps are shown, in other embodiments only a single trap may be utilized, and in yet other embodiments more than two traps may be utilized.

A plurality of valves 140, 141, 142, 144, 146 and 148 are provided to enable regulation of the flow of various materials along the various flow paths extending to and from the reaction chamber. Other valves may be utilized in addition to, or alternatively to, the shown valves.

In operation, precursor materials may be provided in reservoirs 123 and 124, and a reactant may be provided in reservoir 126. Valves 140, 141 and 142 are utilized to control flow of the reactant and precursors so that all them are in chamber 122 at the same time. The reactant and precursors react together form a deposit across a substrate (not shown) which is present within the chamber. The substrate may be, for example, a semiconductor wafer, and the deposit may be, for example, a mixed metal oxide (i.e., hafnium-aluminum oxide).

If exhaust from the chamber contains unreacted precursors, the exhaust may be flowed along the flow path 132 so that the unreacted precursors are trapped on the precursor traps 136 and 138. The unreacted precursors may then be subsequently reclaimed from the traps.

The traps may be operated under conditions so that trapped precursor does not react with reactant flowing past the precursor. Specifically, the exhaust from the CVD process may be a mixture that comprises, for example, reactant, reaction by-products, partially reacted precursor, and unreacted precursor. It may be desired for the traps to specifically trap unreacted precursor, and to then retain such unreacted precursor under conditions that avoid degradation of the precursor. Such conditions may be thermal conditions of a cold trap that are sufficiently cold to preclude reaction of the unreacted precursor with other materials in the exhaust from the CVD process and/or to preclude other mechanisms by which the unreacted precursor may be degraded on the trap. For instance, one of the trapped precursors may correspond to (CH₃)₃(CH₃C₅H₄)Pt, the reactant may include O₂, and the (CH₃)₃(CH₃C₅H₄)Pt may be retained on the trap at a temperature of less than or equal to about −20° C. The trapping temperature utilized during CVD applications may be lower than that of the above-discussed ALD applications both to prevent undesired reaction of trapped precursor with other materials flowing past the trapped precursor, and/or to keep the trapped precursor from being swept off of the trap by the various materials flowing past the trapped precursor.

The system 120 may be subjected to cleaning or other processes in which materials are flowed to the chamber, and in which it is desired that the materials not be flowed across the precursor traps. At such times, the exhaust from the chamber may be flowed along bypass path 134.

The precursors trapped on traps 136 and 138 may be removed from the traps by any suitable methods. For instance, if one or both of the traps is a cold trap, then coils analogous to the coils 44 of FIG. 1 may be provided so that the traps may be heated to release trapped precursor from the traps. Alternatively, or additionally, one or both of the traps may be configured to be easily removed from system 120 so that precursor may be extracted from the trap in an environment separate from system 120. The extracted precursor may then be cleaned, if desired, and then reutilized in a deposition process.

The embodiment of FIG. 4 may be combined with that of FIG. 1 so that multiple traps in series with one another are also duplicated in a parallel arrangement for continuous cycling of precursor materials through a CVD system.

Numerous advantages may be provided by the trapping of precursors, including saving of costs; reducing wastes; and providing for a mechanism of removing of unreacted precursor which may assist in evacuation of a system, and in some embodiments may eliminate utilization of a turbo pump. Among the precursors that may be trapped are precursors comprises metals (either precious metals or non-precious metals); and precursors that may non-expensive, but that are utilized in large quantity, such as, for example, tetraethylorthosilicate.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

I/we claim:

1. A deposition system, comprising:
a reaction chamber;
a plurality of precursor traps in fluid communication with the reaction chamber; the precursor traps being configured to trap precursor under a first condition, and to release the trapped precursor under a second condition;
a flow path along which precursor is flowed to the chamber, through the chamber, and from the chamber; and
wherein at least two of the precursor traps are connected in parallel relative to one another along the flow path so that one of said at least two of the precursor traps may be used as a source of precursor for reactions in the chamber while another of the at least two of the precursor traps is utilized for collecting unreacted precursor exiting from the chamber.

2. The system of claim 1 being configured for utilization in an ALD process.

3. The system of claim 1 being configured for utilization in a CVD process.

4. The system of claim 1 wherein the first and second conditions differ in temperature from one another.

5. An ALD system, comprising:
a reaction chamber;
a pair of alternate flow paths for materials exhausted from the reaction chamber, both of the alternate flow paths leading to a common main pump; a first of said alternate flow paths comprising a precursor trap configured to collect unreacted precursor; a second of said alternate flow paths by-passing the precursor trap; and
at least one flow control structure along said second of the alternate flow paths and configured to preclude back-flow along said second of the alternate flow paths.

6. The ALD system of claim 5 wherein the at least one flow control structure comprises a turbopump, destruct unit, or a cryopump.

7. The ALD system of claim 5 wherein the at least one flow control structure comprises a check-valve.

8. A CVD system, comprising:
a reaction chamber;
a flow path for a mixture of materials exhausted from the reaction chamber, the mixture of materials comprising one or more unreacted precursors; and
at least one precursor trap along the flow path and configured to selectively trap at least one of the one or more unreacted precursors relative to other components of the mixture of materials.

9. The CVD system of claim 8 wherein the precursor trap is a cold trap.

10. The CVD system of claim 8 comprising multiple precursor traps arranged in series along the flow path, the multiple precursor traps being configured to trap different precursor compositions relative to one another.

11. A deposition method, comprising:
flowing precursor through a reaction chamber; the precursor being flowed along a flow path; the flow path extending from upstream of the reaction chamber to the reaction chamber, and from the reaction chamber to downstream of the reaction chamber; some of the precursor reacting while in the reaction chamber, and some of the precursor remaining unreacted while it is in the reaction chamber;
utilizing a plurality of precursor traps along the flow path to recycle the unreacted precursor; the precursor traps being configured to selectively trap and release the precursor; and
alternately cycling the precursor traps between trapping and releasing modes relative to one other so that each of the precursor traps is alternately utilized as a source of precursor upstream of the reaction chamber and utilized for trapping unreacted precursor downstream of the reaction chamber.

12. The deposition method of claim 11 wherein the precursor traps are operated under conditions which retain trapped unreacted precursor at temperatures which preclude oxidation of the trapped unreacted precursor by any oxygen that may be present in the trap.

13. The deposition method of claim 12 wherein the trapped unreacted precursor comprises Rh, and wherein the conditions include a trapping temperature of less than or equal to −40° C.

14. The deposition method of claim 11 wherein the precursor comprises a transition metal and/or a lanthanide series metal.

15. The deposition method of claim 11 being an ALD method.

16. The deposition method of claim 11 being a CVD method.

17. An ALD method, comprising:
flowing a precursor into a reaction chamber;
after flowing the precursor into the reaction chamber, and while reactant is not in the chamber, exhausting material from the reaction chamber along a first flow path; the first flow path extending to a main pump, and including a precursor trap configured to collect unreacted precursor;
after flowing the reactant into the reaction chamber, and while the precursor is not within the reaction chamber, exhausting material from the reaction chamber along a second flow path extending to the main pump and by-passing the precursor trap; and
utilizing at least one flow control structure along the second flow path to preclude back-flow along said second flow path.

18. The ALD method of claim 17 wherein the precursor comprises metal, silicon or germanium; and wherein the reactant comprises oxygen or nitrogen.

19. The ALD method of claim 17 wherein the precursor comprises palladium, platinum, yttrium, aluminum, iridium, silver, gold, tantalum, rhodium, ruthenium or rhenium.

20. The ALD method of claim 17 wherein the precursor comprises (CH₃)₃(CH₃C₅H₄)Pt.

21. The ALD method of claim 20 wherein the reactant comprise one or more of O₂, water and ozone.

22. The ALD method of claim 17 wherein the precursor is flowed into the reaction chamber before the reactant.

23. The ALD method of claim 17 wherein the precursor is flowed into the reaction chamber after the reactant.

24. The ALD method of claim 17 wherein the at least one flow control structure comprises a turbopump, destruct unit or a cryopump.

25. The ALD method of claim 17 wherein the at least one flow control structure comprises a check-valve.

26. A CVD method, comprising:
flowing a mixture of materials into a reaction chamber, the mixture comprising one or more precursors and one or more reactants;
reacting the one or more reactants with the one or more precursors to form a deposit; some of the one or more precursors remaining unreacted;
after the reacting, exhausting the reaction chamber, the exhaust from the reaction chamber comprising the remaining unreacted one or more precursors; and
flowing the exhaust across at least one precursor trap configured to selectively trap at least one of the one or more unreacted precursors relative to other components of the exhaust, the at least one precursor trap being configured to retain the trapped precursor under conditions that preclude reaction of the trapped precursor with other components of the exhaust.

27. The CVD method of claim 26 wherein the at least one precursor trap is operated under conditions which retain trapped unreacted precursor at a temperature which precludes oxidation of the trapped unreacted precursor by any oxygen that may be present in the trap.

28. The deposition method of claim 27 wherein the trapped unreacted precursor comprises Rh, and wherein the conditions include a trapping temperature of less than or equal to −40° C.

29. The CVD method of claim 26 wherein the precursors comprise platinum, the reactants comprise oxygen, and the at least one precursor trap retains unreacted platinum-containing precursor at a temperature less than or equal to about 10° C.

30. The CVD method of claim 26 utilizing a plurality of precursor traps arranged in series along a flow path of the exhaust.
